(19) United States
(12) Patent Application Publication
(10) Pub. No.: US 2024/0387721 A1
(43) Pub. Date: Nov. 21, 2024

(54) SILICON CARBIDE DEVICE WITH TRANSISTOR CELL AND CLAMP REGION

(71) Applicant: Infineon Technologies AG, Neubiberg (DE)

(72) Inventors: Joachim Weyers, Höhenkirchen (DE); Wout Anita T . Jansen, Wernberg (DE); Bernhard Brunner, Feldkirchen (AT); Thomas Ralf Siemieniec, Villach (AT)

(21) Appl. No.: 18/655,492

(22) Filed: May 6, 2024

(30) Foreign Application Priority Data
May 17, 2023 (DE) 102023204606.7

(51) Int. Cl. H01L 29/78; H01L 29/06; H01L 29/16; H01L 29/417; H01L 29/423

(52) U.S. Cl. CPC H01L 29/7802; H01L 29/0611; H01L 29/1608; H01L 29/41741; H01L 29/42356

(57) ABSTRACT

A silicon carbide device that includes a transistor cell is described. The transistor cell may include a gate electrode and a source region. The silicon carbide device may further include a first clamp region of a first conductivity type electrically connected with the gate electrode and a second clamp region of the first conductivity type electrically connected with the source region. The silicon carbide device may further include a well region of a second conductivity type laterally surrounding each of the first clamp region and the second clamp region. A shortest distance between the first clamp region and the second clamp region may be equal to or less than 10 μm.

### TECHNICAL FIELD

Examples of the present disclosure relate to a silicon carbide device with transistor cells, in particular to a semiconductor device with an insulated gate transistor cell and a clamp between a gate electrode and a source electrode of the transistor cell.

### BACKGROUND

Power semiconductor devices are typically used as switches and rectifiers in electric circuits for transforming electrical energy, for example, in DC/AC converters, AC/AC converters or AC/DC converters, and in electric circuits that drive heavy inductive loads, e.g. in motor driver circuits. Since the dielectric breakdown field strength of silicon carbide (SiC) is high compared to silicon (Si), SiC power devices may be significantly thinner and may show lower on-state resistance than their silicon counterparts. Integrated protection elements and/or protection circuits can increase device reliability. For example, overvoltage events such as electrostatic discharge events may cause malfunction of the device.

### SUMMARY

According to an embodiment, a silicon carbide device may comprise a transistor cell. The transistor cell may comprise a gate electrode and a source region. The silicon carbide device may further comprise a first clamp region of a first conductivity type electrically connected with the gate electrode and a second clamp region of the first conductivity type electrically connected with the source region. The silicon carbide device may further include a well region of a second conductivity type laterally surrounding each of the first clamp region and the second clamp region. A shortest distance between the first clamp region and the second clamp region may be equal to or less than 10 μm.

Laterally surrounding may mean that the well region surrounds the first clamp region and the second clamp region in a lateral direction (that is substantially parallel to a main surface of the semiconductor body) on all sides within the silicon carbide body. For example, the well region may form a contiguous shell enclosing the first clamp region and the second clamp region in the silicon carbide body in the lateral direction.

In one or more embodiments, the well region may comprise an intermediate region located between the first clamp region and the second clamp region. A width of the intermediate region may be less than a width of at least one of: the first clamp region or a width of the second clamp region. The width of the intermediate region, the width of the first clamp region and the width of the second clamp region may be given along a direction that points along the shortest distance between the first clamp region and the second clamp region.

In an embodiment, the shortest distance between the first clamp region and the second clamp region may be equal to or less than 5 μm.

According to an embodiment, the first clamp region and the second clamp region may form a bidirectional clamp that may be configured to carry a breakdown current of at least 0.33 A.

In an embodiment the well region, the first clamp region, and the second clamp region may extend from a first main surface of the silicon carbide device into the silicon carbide device.

In some embodiments the silicon carbide device may further comprise a gate metallization. The gate metallization and the gate electrode may be electrically connected and the gate metallization and the first clamp region may form a low-resistivity ohmic contact. The silicon carbide device may further comprise a load metallization. The load metallization and the source region may form a low-resistivity ohmic contact. The load metallization and the second clamp region may form a low-resistivity ohmic contact.

In other embodiments, the silicon carbide device may comprise a first metal layer disposed over the first clamp region. The silicon carbide device may further comprise a gate metallization that may be electrically connected to the gate electrode. The gate metallization and the first metal layer may be electrically connected. In some embodiments, the first metal layer may comprise at least one of Ti, TiN, MoN, TaN and Ni.

In addition, or as an alternative, the silicon carbide device may further comprise a second metal layer disposed over the second clamp region. The silicon carbide device may further include a load metallization. The load metallization and the source region may form a low-resistivity ohmic contact and the load metallization and the second metal layer may be electrically connected. In some embodiments, the second metal layer comprises at least one of Ti, TiN, MoN, TaN and Ni.

In embodiments, the first clamp region may form a shape of a first comb, and the second clamp region may form a shape of a second comb. The first comb may comprise a first shaft and a plurality of first teeth. The second comb may comprise a second shaft and a plurality of second teeth. The plurality of first teeth may be facing towards the second shaft. The plurality of second teeth may be facing towards the first shaft. The plurality of first teeth and the plurality of second teeth may extend substantially parallel to each other.

In one or more embodiments, a distance between a first tooth of the plurality of first teeth and the second shaft may be equal to or greater than a distance between the first tooth and a second tooth of the plurality of second teeth. The distance between the first tooth of the plurality of first teeth and the second tooth of the plurality of second teeth may be the shortest distance between the first clamp region and the second clamp region.

In some embodiments the silicon carbide device may further comprise a first metal layer disposed over the first shaft and over at least a portion of each of the plurality of first teeth. The silicon carbide device may further comprise a gate metallization. The gate metallization and the gate electrode may be electrically connected and the gate metallization and the first metal layer may be electrically connected. In embodiments, the first metal layer may comprise at least one of Ti, TiN, MoN, TaN and Ni.

In addition, or as an alternative, the silicon carbide device may further comprise a second metal layer disposed over the second shaft and over at least a portion of each of the plurality of second teeth. The silicon carbide device may further comprise a load metallization. The load metallization and the source region may form a low-resistivity ohmic contact. The load metallization and the second metal layer may be electrically connected. In embodiments, the second metal layer each comprises at least one of Ti, TiN, MoN, TaN and Ni.

In embodiments, the gate metallization may comprise a plurality of first fingers that partially cover the first metal layer. The load metallization may comprise a plurality of second fingers that partially cover the second metal layer.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A-1B show schematic vertical cross-sectional views of portions of silicon carbide devices with clamp regions of bidirectional clamps.

FIG. 1C shows a simplified circuit diagram of the silicon carbide devices of FIGS. 1A-1B.

FIGS. 2A-2B show schematic vertical cross-sectional views of portions of silicon carbide devices with clamp regions, gate metallization, first load metallization and second load metallization.

FIG. 3 shows a schematic vertical cross-sectional view of a portion of a silicon carbide device with transistor cells and an integrated bidirectional clamp according to an embodiment.

FIG. 4 shows a schematic plan view of a silicon carbide device indicating possible areas for a bidirectional clamp.

FIG. 5 shows a schematic vertical cross-sectional view of portions of silicon carbide devices with an integrated bidirectional clamp formed below a gate runner and an edge conductor.

FIGS. 6A-6B show a simplified plan view and a corresponding simplified vertical cross-sectional view of a portion of a silicon carbide device with a bidirectional clamp with a first clamp region connected to a gate pad and with a second clamp region connected to a load pad.

FIG. 7A shows a schematic side view of a silicon carbide device in accordance with FIGS. 1-6B indicating a (shortest) distance between the first clamp region and the second clamp region.

FIG. 7B shows a schematic side view of a silicon carbide device in accordance with FIGS. 1-7A indicating a (shortest) distance between the first clamp region and the second clamp region, which is reduced as compared to FIG. 7A.

FIG. 8 shows a schematic side view of a silicon carbide device in accordance with FIGS. 1-7B indicating a (shortest) distance between the first clamp region and the second clamp region, which is reduced as compared to FIG. 7A.

FIG. 9A shows a top view of a silicon carbide device in accordance with FIGS. 1-8 indicating a (shortest) distance between the first clamp region and the second clamp region, which is reduced as compared to FIG. 7A.

FIG. 9B shows a three dimensional view of the silicon carbide device of FIG. 9A indicating a (shortest) distance between the first clamp region and the second clamp region, which is reduced as compared to FIG. 7A.

FIG. 9C shows a top view of an exemplary silicon carbide device.

FIG. 10 shows a top view of a silicon carbide device in accordance with FIGS. 1-9B indicating a (shortest) distance between the first clamp region and the second clamp region, which is reduced as compared to FIG. 7A.

### DETAILED DESCRIPTION

In the following detailed description, reference is made to the accompanying drawings, which form a part hereof and in which are shown by way of illustrations specific embodiments in which a silicon carbide device may be practiced. It is to be understood that other embodiments may be utilized and structural or logical changes may be made without departing from the scope of the present disclosure. For example, features illustrated or described for one embodiment can be used on or in conjunction with other embodiments to yield yet a further embodiment. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

The term “electrically connected” may describe a permanent low-resistive ohmic contact between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state. The term an “ohmic contact” may describe a non-rectifying electrical junction between two electrically connected elements. The ohmic contact may have a linear or approximately linear current-voltage (I-V) characteristic such as a linear I-V curve in the first and third quadrant of the I-V diagram as with Ohm's law.

The Figures illustrate relative doping concentrations by indicating “−” or “+” next to the doping type “n” or “p”. For example, “n-” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

Two adjoining doping regions of the same conductivity type and with different dopant concentrations may form a unipolar junction, e.g., an n/n+ or p/p+ junction along a boundary surface between the two doping regions. At the unipolar junction a dopant concentration profile orthogonal to the unipolar junction may show a step or a turning point, at which the dopant concentration profile changes from being concave to convex, or vice versa.

Ranges given for physical dimensions include the boundary values. For example, a range for a parameter y from a to b reads as a≤y≤b. The same holds for ranges with one boundary value like “at most” and “at least”.

The term “on” is not to be construed as meaning “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

The terms “power semiconductor device” and “SiC power device” may refer to semiconductor devices with a high voltage blocking capability of at least 30 V, for example 100 V, 600 V, 1.6 kV, 3.3 kV or more and with a nominal on-state current or forward current of at least 1 A, for example 10 A or more.

A silicon carbide device may include a transistor cell with a gate electrode and a source region. The source region may be formed in a silicon carbide body and has a conductivity type (e.g. a first conductivity type).

The silicon carbide body may have two essentially parallel main surfaces (such as a first main surface and a second main surface), which may have approximately the same shape and size, and a lateral surface connecting the edges of the two main surfaces. For example, the silicon carbide body may be a cylinder or a polygonal, e.g. rectangular or hexagonal, prism with or without rounded edges. The silicon carbide body may have a surface extension along two horizontal directions and may have a thickness along a vertical direction perpendicular to the horizontal directions. The horizontal directions are also referred to as lateral directions in the following.

The material of the silicon carbide body may be single-crystalline silicon carbide, for example 15R-SiC (silicon carbide of 15R-polytype), or silicon carbide with hexagonal polytype like 2H-SiC, 4H-SiC or 6H-SiC, by way of example. In addition to the main constituents silicon and carbon, the silicon carbide body may include dopant atoms, for example nitrogen (N), phosphorous (P), beryllium (Be), boron (B), aluminum (Al) and/or gallium (Ga). The silicon carbide body may include further impurities, for example hydrogen, fluorine and/or oxygen.

The transistor cell may be or may include an insulated gate transistor cell with an insulated gate electrode. The gate electrode may be a planar gate electrode formed on a first main surface of the silicon carbide body or may be a trench gate electrode formed in a trench extending from a first main surface into the silicon carbide body.

The silicon carbide body may further include a drain/drift region. At least a portion of the drain/drift region may have the same conductivity type as the source region and may be effective as the drain of the transistor cell.

The transistor cell may further include a body region of a complementary conductivity type as the source region and the drift/drain region. The body region may spatially separate the source region and the portion of the drain/drift region. A gate dielectric may be formed between the gate electrode and the body region. An electric potential applied to the gate electrode controls the distribution of mobile charge carriers in the body region by a field effect.

The silicon carbide device (as described above) may further include a first clamp region that extends into a well region of the silicon carbide device. The first clamp region may have a first conductivity type. The well region may have a second conductivity type (being complementary to the first conductivity type). The first clamp region and the well region may form a pn junction. The well region may laterally surround the first clamp region within the silicon carbide body. A first low-resistive ohmic path may electrically connect the first clamp region and the gate electrode. The ohmic resistance of the first low-resistive ohmic path may be at most 2Ω, e.g. at most 1Ω, or at most 0.5Ω. The well region may be floating or may be connected to other doped regions of the same conductivity type through a comparatively high-ohmic connection. The well region may have a first mean net dopant density N₁.

The silicon carbide device (as described above) may further include a second clamp region that extends into the well region of the silicon carbide device. The second clamp region may have the first conductivity type. The second clamp region and the well region may form a pn junction. The well region may laterally surround the second clamp region within the silicon carbide body. The first clamp region and the second clamp region may be laterally separated. A second low-resistive ohmic path may electrically connect the second clamp region and the source region. The ohmic resistance of the second low-resistive ohmic path may be at most 2Ω, e.g. at most 1Ω, or at most 0.5Ω.

The first clamp region, the well region and the second clamp region may form a first bidirectional clamp effective between the gate electrode and the source region. An avalanche breakdown of the pn junction between the first clamp region and the well region may define the clamp voltage for positive voltage transients between gate electrode and source region. The transient is directly short-circuited through the forward-biased pn junction between the well region and the second clamp region. An avalanche breakdown of the pn junction between the second clamp region and the well region may define an upper clamp voltage for negative voltage transients between the gate electrode and the source region.

In case the well region is floating or has a sufficiently high-ohmic connection to the source region and, in addition, has sufficient distance to other doped regions of the second conductivity type and connected to the source region, the avalanche breakdown of the pn junction between the second clamp region and the well region may define the clamp voltage for negative voltage transients between the gate electrode and the source region. Both clamp voltages may have the same amount. The bidirectional clamp may be symmetric.

In other embodiments, the bidirectional clamp may have a clamp voltage for negative voltage transients and a clamp voltage for positive transients that are different from each other. In this case, the bidirectional clamp is asymmetric.

The silicon carbide device (as described further above) may also include a doped region formed in the silicon carbide body. The doped region may comprise a buried region and one or more lateral regions. For example, the doped region may be or may include a horizontally contiguous structure including portions of different vertical extension and/or with different vertical dopant profiles. The doped region may be a one-part structure or may be a multi-part structure. For example, the doped region may include two or more individual portions, which are laterally and/or vertically separated within the silicon carbide body. The individual portions of a multi-part doped region may be electrically connected through low-resistive ohmic paths.

In a first exemplary bidirectional clamp, the doped region (such as the buried region and the one or more lateral regions) may be of the same conductivity type as the well region (such as, the second conductivity type). In this case, the doped region and the well region may form a unipolar junction at the interface between the well region and the doped region. The doped region may have a second mean net dopant density N₂. The second mean net dopant density N₂ may be higher than the first mean net dopant density N₁ of the well region. For example, the second mean net dopant density N₂ may be at least two times, at least five times or at least ten times higher than the first mean net dopant density N₁. In this embodiment, the first clamp region and the second clamp region may be of the same conductivity type as the source region and the drift/drain region of the silicon carbide device (i.e., the first conductivity type). In addition, the well region and the doped region may be of the same conductivity type as the body region (i.e., the second conductivity type). In one particular example of this embodiment, the first clamp region, the second clamp region, the source region, and the drift/drain region are of an n-conductivity type (with potentially different doping concentrations); and the well region, the doped region, and the body region are of a p-conductivity type (with potentially different doping concentrations). In a particular embodiment, the first clamp region, the second clamp region and the source region of the first exemplary bidirectional clamp may be of a negative conductivity type, and the doped region, the body region, and the well region of the first exemplary bidirectional clamp may be of a positive conductivity type. An example for the first exemplary bidirectional clamp is disclosed in US 2022/0102487 A1, which is hereby incorporated by reference.

In a second exemplary bidirectional clamp, the doped region (such as the buried region and the one or more lateral regions) may be of a complementary conductivity type as the well region (such as the doped region being of the first conductivity type and the well region being of the second conductivity type). In this case, the doped region and the well region may form a pn-junction at the interface between the well region and the doped region. In this embodiment, the first clamp region and the second clamp region may be of a complementary conductivity type as the source region and the drift/drain region of the silicon carbide device (i.e., the first clamp region and the second clamp region may be of the first conductivity type while the source region and the drift/drain region are of the second conductivity type). In addition, first clamp region and the second clamp region may be of the same conductivity type as the body region (i.e., the first conductivity type). In one particular example of this embodiment, the first clamp region, the second clamp region, the doped region, and the body region are of a p-conductivity type (with potentially different doping concentrations); and the well region, the source region, and the drain/drift region are of an n-conductivity type (with potentially different doping concentrations). In a particular embodiment, the first clamp region, the second clamp region, the body region and the doped region of the second exemplary bidirectional clamp may be of a positive conductivity type, and the source region and the well region of the second exemplary bidirectional clamp may be of a negative conductivity type. An example of the second exemplary bidirectional clamp is disclosed in US 2022/0102549 A1, which is hereby incorporated by reference.

The first and second exemplary bidirectional clamps described above may protect the transistor cell against overvoltage events. In particular the bidirectional clamp may reliably protect the gate dielectric, which in silicon carbide power devices can be to a high degree susceptible for overvoltage events, against electrostatic discharge (ESD) events.

Due to the relatively high intrinsic breakdown voltage of silicon carbide, the bidirectional clamp formed in the silicon carbide body may short-circuit and dissipate overvoltage events, e.g. ESD events, without being damaged. Due to the large band gap and the low intrinsic thermal carrier generation of silicon carbide, the leakage current through the bidirectional clamp may be low compared to equivalent circuits in single crystalline silicon or in polycrystalline silicon.

The above-discussed bidirectional clamps may be configured to carry a breakdown current of at least 0.33 A or for example 2 A to 3 A (or up to 5 A). Suitably configured bidirectional clamps may facilitate dissipating standard ESD pulses according to the human body model without persistent damage of the silicon carbide body and the transistor cells.

The silicon carbide device may further include a gate metallization. The gate metallization may be formed on the first main surface at the front side of the silicon carbide body. The gate metallization may include a gate pad from a metallic material and/or one or more gate conductors from a metallic material. The metallic material may include one or more elemental metals, e.g. copper (Cu), aluminum (Al), titanium (Ti) or tantalum (Ta), one or more metal alloys, e.g. copper aluminum (CuAl), and/or one or more metal compounds, e.g. a metal silicide or a metal nitride.

The gate metallization and the gate electrode may be electrically connected to each other. For example, the gate metallization may include a metallic gate contact structure extending from the gate pad and/or the gate conductor to the gate electrode, wherein the gate contact structure and the gate electrode form a low-resistive ohmic contact. In addition, the gate metallization and the first clamp region may form a low-resistive ohmic contact. For example, the gate metallization may include a metallic clamp contact structure extending from the gate pad and/or the gate conductor to the first clamp region, wherein the clamp contact structure and the first clamp region form a low-resistive ohmic contact. By forming the first clamp region directly below a portion of the gate metallization, the first clamp region of the bidirectional clamp may be integrated in a space-saving and area-efficient way.

The silicon carbide device may include a first load metallization. The first load metallization may be formed on the first main surface at the front side of the silicon carbide body. The first load metallization may include a load pad from a metallic material and/or one or more edge conductors from a metallic material. The metallic material may include one or more elemental metals, e.g. copper (Cu), aluminum (Al), titanium (Ti) or tantalum (Ta), one or more metal alloys, e.g. copper aluminum (CuAl), and/or one or more metal compounds, e.g. a silicide or a nitride.

The first load metallization and the source region may be electrically connected to each other. For example, the first load metallization may include a metallic load contact structure extending from the load pad to the source region, wherein the load contact structure and the source region form a low-resistive ohmic contact. The first load metallization and the second clamp region may form a low-resistive ohmic contact. The load pad and/or an edge conductor may be formed directly on a portion of the second clamp region, wherein the second clamp region and the load pad and/or the second clamp region and the edge conductor form a low-resistive ohmic contact. Alternatively, the first load metallization may include one or more further metal load contact structures extending from the load pad to or into the second clamp region, wherein the second clamp region and the further load contact structure form a low-resistive ohmic contact. According to a further example, the first load metallization may include one or more metal edge contact structures extending from the edge conductor to or into the second clamp region, wherein the second clamp region and the edge contact structure form a low-resistive ohmic contact.

The following detailed description of the drawings relates to the first exemplary bidirectional clamp (as discussed above). However, the concepts of the present disclosure may also be applied to the second exemplary bidirectional clamp (as discussed above) so that the discussions with regard to the first exemplary bidirectional clamp are not intended to limit the scope of the present disclosure to the first exemplary bidirectional clamp, but the scope also includes other bidirectional clamps (such as the second exemplary bidirectional clamp discussed above).

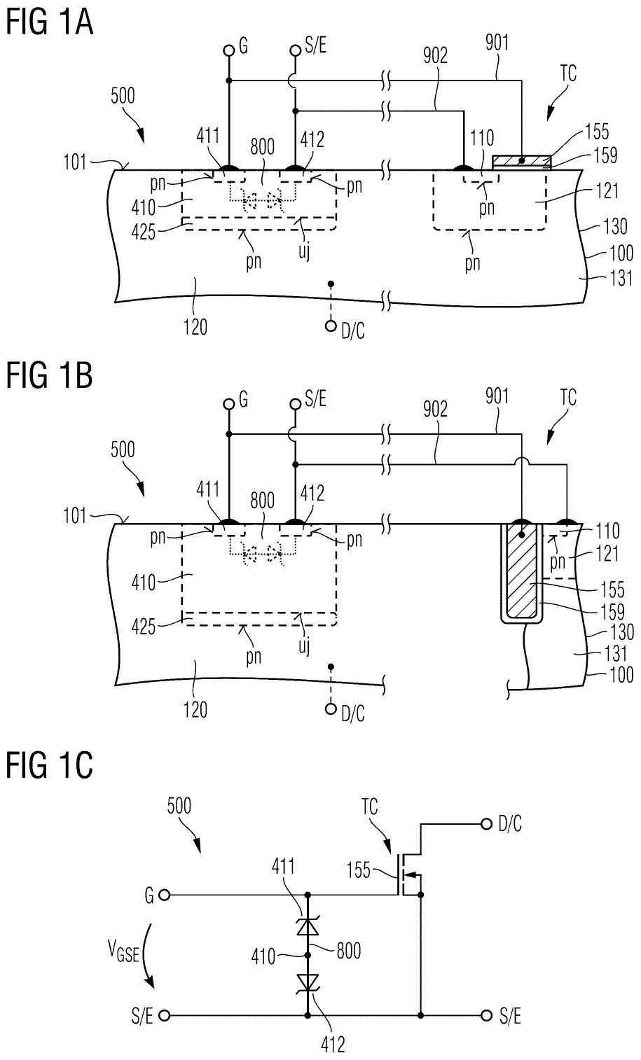

FIGS. 1A-1C refer to silicon carbide devices 500 with a monolithically integrated bidirectional clamp 800. Each silicon carbide device 500 may be or may include an IGFET (insulated gate field effect transistor), for example an MOSFET (metal oxide semiconductor FET) or an IGBT (insulated gate bipolar transistor).

The silicon carbide body 100 shown in FIGS. 1A-1B includes or consists of single crystalline silicon carbide, e.g., a silicon carbide crystal including the main constituents silicon and carbon. The silicon carbide crystal may include dopant atoms and further impurities like hydrogen, fluorine and/or oxygen. The polytype of the silicon carbide crystal may be 15R or may be hexagonal, e.g. 2H, 6H, or 4H. The silicon carbide body 100 may include or consist of a silicon carbide layer grown by epitaxy.

A first main surface 101 at a front side of the silicon carbide body 100 may be planar or ribbed. A mean plane of the first main surface 101 extends along horizontal directions. The mean plane of a planar first main surface 101 is identical with the planar first main surface 101. In case of a non-planar first main surface 101, for example in case of a ribbed first main surface 101, the mean plane may be a planar least squares plane. Position and orientation of the planar least squares plane are defined such that the sum of the squares of the deviations of surface points of the ribbed first main surface 101 from the planar least squares plane has a minimum.

A vertical direction is orthogonal to the horizontal directions, e.g. parallel to the surface normal onto the mean plane. The horizontal directions are also referred to as lateral directions in the following. The vertical direction may coincide with a main lattice direction or may be tilted to a main lattice direction by an off-axis angle, wherein the off-axis angle may be in a range from 2° to 8°, in particular about 4°. Opposite to the front side, a second main surface may extend parallel to the planar first main surface 101 or parallel to the least squares plane of a ribbed first main surface 101.

The silicon carbide device 500 may include a plurality of insulated gate transistor cells TC electrically connected in parallel and formed at the front side of the silicon carbide body 100. A drain/drift region 130 laterally extends through the silicon carbide body 100 between the insulated gate transistor cells TC and the second main surface. The drain/drift region 130 may include a voltage sustaining structure, e.g., a lightly doped drift zone 131.

Each insulated gate transistor cell TC may include a source region 110 and a body region 121. The source region 110 and the body region 121 are doped portions of the silicon carbide body 100. The source region 110 has a first conductivity type. The body region 121 has a second conductivity type. For example, the source region 110 is n conducting, the body region 121 is p conducting, and the drift zone 131 is n conducting.

The body region 121 may form part of a contiguous doped region of the second conductivity type, wherein the doped region includes further portions, for example a junction termination portion, a shielding portion, and/or a contact portion, by way of example.

A well region 410 of the second conductivity type extends from the first main surface 101 into the drain/drift region 130. The well region 410 and the drain/drift region 130 may form a pn junction. The drain/drift region 130 may surround the well region 410 on all sides within the silicon carbide body 100.

The well region 410 may include a lower doped main portion (not shown) and a more heavily doped enhanced portion (not shown). The enhanced portion may extend from the first main surface 101 into the well region 410. A first part of the enhanced portion may laterally extend from the first clamp region 411 to the second clamp region 412. A second part of the enhanced portion may surround the first clamp region 411, the second clamp region 412 and the first part of the enhanced portion 415. The second part of the enhanced portion 415 may be spaced from a lateral boundary of the well region 410 or may extend up to the lateral boundary of the well region 410. The lower doped main portion may be located below the enhanced portion.

The body regions 121 of the transistor cells TC and the well region 410 may have the same vertical dopant profile and may result from the same ion implantation process(es). In particular, one single implant mask may define the well region 410 and the body region 121.

A first clamp region 411 of the first conductivity type may extend from the first main surface 101 into the well region 410. The first clamp region 411 and the well region 410 may form a pn junction. The well region 410 surrounds the first clamp region 411 on all sides within the silicon carbide body 100.

A second clamp region 412 of the first conductivity type may extend from the first main surface 101 into the well region 410. The second clamp region 412 and the well region 410 form a pn junction. The well region 410 surrounds the second clamp region 412 on all sides within the silicon carbide body 100. The first clamp region 411 and the second clamp region 412 are laterally separated.

The source regions 110 of the transistor cells TC, the first clamp region 411, and the second clamp region 412 may have the same vertical dopant profile and may result from the same ion implantation process(es). In particular, one single implant mask may define the source regions 110, the first clamp region 411, and the second clamp region 412.

A first low-resistive ohmic path 901 electrically connects the first clamp region 411 and the gate electrodes 155 of the transistor cells TC. A gate terminal G and the first low-resistive ohmic path 901 are electrically connected.

A second low-resistive ohmic path 902 electrically connects the source regions 110 and the body regions 121 of the transistor cells TC with the second clamp region 412. A first load terminal S/E and the second low-resistive ohmic path 902 are electrically connected.

The first load terminal S/E may be the source terminal of an MOSFET or the emitter terminal of an IGBT. The drain/drift region 130 is electrically connected or coupled through a further pn junction to a second load terminal D/C. The second load terminal D/C may be the drain terminal of an MOSFET or the collector terminal of an IGBT.

A p⁺ conductive buried region 425 may be formed between the well region 410 and the drain/drift region 130. The buried region 425 and the well region 410 may form a unipolar junction. The buried region 425 and the drain/drift region 130 form a pn junction. A mean net dopant density N₂ of the buried region 425 is higher than a mean net dopant density N₁ in the well region 410. The buried region 425 shields the well region 410 with the first and second clamp region 411, 412 against the potential applied to the drain/drift region 130.

The first clamp region 411, the well region 410 and the second well region 412 may form a bidirectional clamp 800. The silicon carbide device 500 may include a plurality of spatially separated well regions 410 with first and second clamp regions 411, 412, wherein the bidirectional clamps 800 of different well regions 410 may be electrically connected in series or in parallel.

In FIG. 1A the transistor cell TC includes a planar gate electrode 155 formed on the first main surface 101. A gate dielectric 159 formed on the first main surface 101 separates the body region 121 and the gate electrode 155.

In FIG. 1B the transistor cell TC includes a trench gate electrode 155 formed in a trench that extends from the first main surface 101 into the silicon carbide body 100. The gate dielectric 159 may line the trench and may separate at least the body region 121 and the gate electrode 155.

According to FIG. 1C the bidirectional clamp 800 clamps a gate voltage V_{GSE} between the gate terminal G and the first load terminal S/E. For n-channel transistor cells TC, the positive clamp voltage is defined by the avalanche breakdown voltage of the pn junction between well region 410 and the first clamp region 411. An upper boundary for the amount of the negative clamp voltage is defined by the avalanche breakdown voltage of the pn junction between the well region 410 and the second clamp region 412.

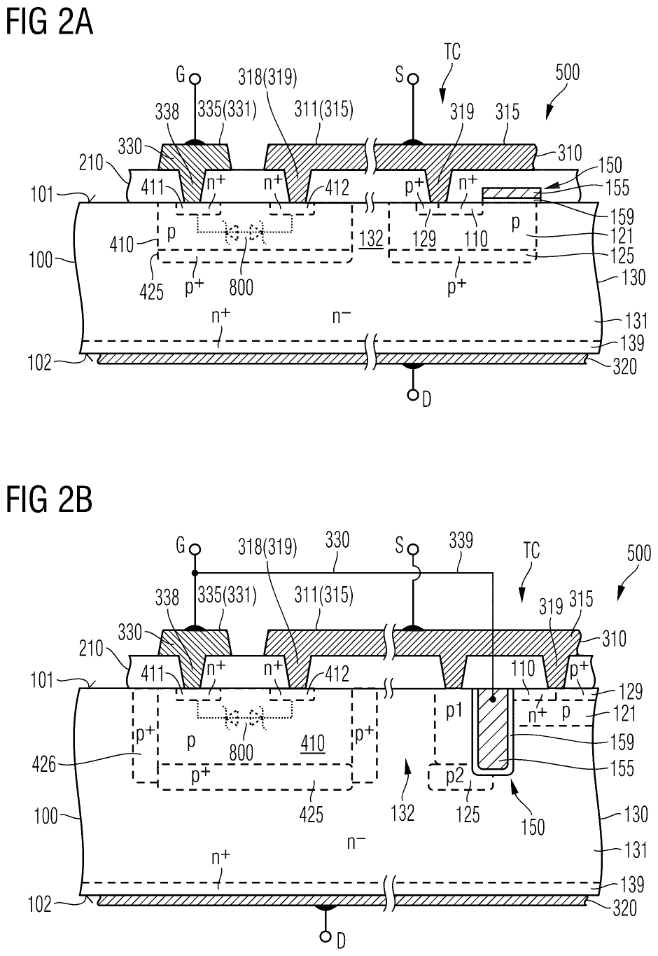

In FIGS. 2A-2B the silicon carbide devices 500 are n-channel MOSFETs with n⁺ conductive source regions 110 electrically connected to source terminals S, n⁻ conductive drift zones 131, p conductive well region 410, and n⁺ conductive first and second clamp regions 411, 412. For example, the p conductive well region 410 may be floating.

An interlayer dielectric 210 is formed on the first main surface 101. A first load metallization 310 and a gate metallization 330 are formed on the front side. The first load metallization 310 includes a load pad 315 and edge conductors 311 formed on the interlayer dielectric 210. The first load metallization 310 further includes load contact structures 319 extending from the load pad 315 through openings in the interlayer dielectric 210 to the source regions 110, to the body regions 121, and, if applicable, to the second clamp region 412. Alternatively or in addition, the first load metallization 310 may include edge contact structures 318 extending from the edge conductor 311 through openings in the interlayer dielectric 210 to the second clamp region 412.

Along the interface to the load contact structure 319, the body region 121 may include a heavily doped body contact region 129, wherein the load contact structure 319 and the body contact region 129 form a low-resistive ohmic metal/semiconductor contact.

The gate metallization 330 includes a gate pad 335 and gate conductors 331 formed on the interlayer dielectric 210. The gate metallization 330 further includes gate contact structures 339 extending from the gate pad 335 and/or from the gate conductor 331 through openings in the interlayer dielectric 210 to the gate electrodes 155. The gate metallization 330 may include clamp contact structures 338 extending from the gate pad 335 and/or from the gate conductor 331 through openings in the interlayer dielectric 210 to the first clamp regions 411.

The first load metallization 310 at the front side forms or is electrically connected with the source terminal S. A second load metallization 320 is in contact with the second main surface 102 on the back side and forms or is electrically connected with the drain terminal D. The drain/drift region 130 includes a more heavily doped n⁺ conductive contact layer 139 along the second main surface 102, wherein the contact layer 139 and the second load metallization 320 form a low-resistive ohmic contact.

An n⁻ conductive front side portion 132 of the drain/drift region 130 may extend from the first main surface 101 to a layer portion of the drain/drift region 130 below the well region 410. The front side portion 132 may be laterally between the well region 410 and neighboring p conductive regions, e.g., a doped well including the body regions 121 of the transistor cells TC and/or p conductive regions of termination structures such as a JTE (junction termination extension), a VLD (variation of lateral doping) region and/or guard rings.

FIG. 2A illustrates a silicon carbide device 500 with planar gate structure 150 and with a front side portion 132 of the drain/drift region 130 between the well region 410 and a p conductive doped well including the body region 121 of a transistor cell TC. The p conductive, doped well may include a shielding region 125 between the body region 121 and the drain/drift region 130. The shielding region 125 has a higher maximum net dopant concentration than the body region 121.

The shielding regions 125 of the transistor cells TC and the buried region 425 along the well region 410 may be formed at a same distance to the first main surface 101, may have the same vertical dopant profile, and may result from the same ion implantation process(es). In particular, one single implant mask may define the shielding region 125 and the buried region 425.

FIG. 2B illustrates a silicon carbide device 500 with trench gate structure 150 and asymmetric transistor cells TC, wherein an inversion channel is formed only at an active sidewall of the trench gate structure 150. The source region 110 and the body region 121 are formed only along the active sidewall.

A shielding region 125 is formed along a lower portion of the inactive sidewall and along a directly adjoining section of the trench gate structure bottom surface. The shielding region 125 has a higher maximum net dopant concentration than the body region 121.

The shielding regions 125 of the transistor cells TC and the buried region 425 along the well region 410 may be formed at a same distance to the first main surface 101, may have the same vertical dopant profile, and may result from the same ion implantation process(es). In particular, one single implant mask may define the shielding region 125 and the buried region.

A connection region 126 extends along the inactive sidewall of the trench gate structure 155 from the first main surface 101 to the shielding region 125. The connection region 126 has a higher mean net dopant concentration than the body region 121. Along the first main surface 101 a dopant concentration in the connection region 126 is high enough such that the first load metallization 310 and the connection region 126 form a low-resistive ohmic contact.

A lateral region 426 laterally surrounds the well region 410. The lateral region 426 and the well region 410 form a unipolar junction. The lateral region 426 and the drain/drift region 130, in particular the lateral region 426 and the front side portion 132 of the drain/drift region 130 form a vertical pn junction. The lateral region 426 extends from the first main surface 101 to or into the buried region 425. The buried region 425 and the lateral region 426 may laterally surround the well region 410 (such as form a contiguous shell enclosing the well region 410 in the silicon carbide body 100).

The connection regions 126 of the transistor cells TC and the lateral region 426 along the well region 410 may have the same vertical dopant profile and may result from the same ion implantation process(es). In particular, one single implant mask may define the connection region 126 and the lateral region 426.

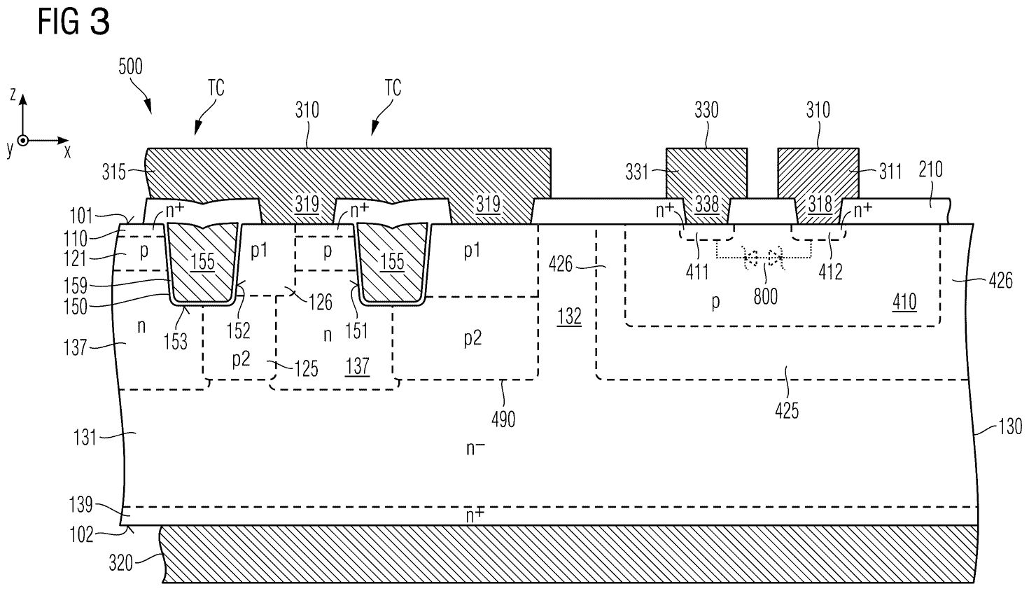

FIG. 3 shows a silicon carbide device 500 which includes a silicon carbide body 100, a first load metallization 310, a gate metallization 330, a drain/drift region 130, a well region 410, a first clamp region 411, a second clamp region 412, a buried region 425 and a lateral region 426 as described with reference to FIGS. 2A-2B and 3.

The silicon carbide device 500 includes a plurality of transistor cells TC with stripe-shaped trench gate structures 150. Longitudinal axes of the gate structures 150 extend along a horizontal direction parallel to a y-axis. Each gate structure 150 includes a conductive gate electrode 155 and a gate dielectric 159 between the gate electrode 155 and the silicon carbide body 100. The gate electrode 155 may include heavily doped polycrystalline silicon. The gate dielectric 159 may consist of or may include silicon oxide, silicon nitride and/or siliconoxynitride.

An active sidewall 151 of each gate structure 150 may be parallel or at least approximately parallel to a crystal plane with high charge carrier mobility, e.g. parallel to a <11-20> lattice plane. The active sidewall 151 may be tilted to the vertical z-axis by an off-axis angle of about 4 degrees.

The source region 110 of each transistor cell TC is formed along the first main surface 101 and in contact with the active sidewall 151. The body region 121 forming pn junctions with the source region 110 and the drain/drift region 130 is in contact with the active sidewall 151 and vertically separates the source region 110 and the drain/drift region 130. The drain/drift region 130 may include a lightly doped drift zone 131, more heavily doped current spread regions 137 between the drift zone 131 and the body regions 121 and a heavily doped contact portion 139 formed along the second main surface 102.

A shielding region 125 is in contact with a portion of the gate structure bottom surface 153 at a side opposite to the active sidewall 151 and may extend from the bottom surface 153 into the direction of the second main surface 102. The shielding region 125 and the drain/drift region 130 form a pn junction.

A connection region 126 with the conductivity type of the shielding region 125 extends along the inactive sidewall 152 from the first main surface 101 to or into the shielding region 125 and may form a unipolar junction with the body region 121 of the neighboring transistor cell TC. At least along the first main surface 101, a dopant concentration in the connection regions 126 is sufficiently high such that the connection regions 126 and the metal load contact structures 319 form low-resistive ohmic semiconductor/metal contacts. A front side portion 132 of the drain/drift region 130 may laterally separate the lateral region 426 and the neighboring p doped regions of the transistor cells TC.

A mean net dopant concentration in the lateral region 426 and a mean net dopant concentration in the buried region 425 are sufficiently high to avoid an unintentional turn on of the parasitic npn bipolar transistor including the n doped clamp regions 411, 412, the p doped well region 410 and the n doped drift zone 131. Formation of the well region 410, the lateral region 426 and the buried region 425 may share implantation steps used for forming the body regions 121, the connection regions 126 and the shielding regions 125 of the transistor cells TC and may be defined by modifying existing implant masks for the body region, the shielding region 125 and the connection region 126.

A maximum net dopant concentration in the first and second clamp regions 411, 412 is selected sufficiently high to form low-resistive ohmic contacts between the first clamp region 411 and the gate metallization 330 and between the second clamp region 412 and the source metallization 310, and is selected sufficiently low to achieve the desired breakdown voltage for the bidirectional clamp, e.g. a breakdown voltage of at least 100V, 80V, 60V, 50V or 30V. The maximum net dopant concentration in the first and second clamp regions 411, 412 may be equal to or approximately equal to the maximum net dopant concentration in the source regions 110.

In addition, FIG. 3 shows auxiliary well structure 490 formed at a lateral distance di to the conductive structure formed by the well region 410, the lateral region 426 and the buried region 425. The auxiliary well structure 490 and the first load metallization 310 may form a low resistive ohmic contact.

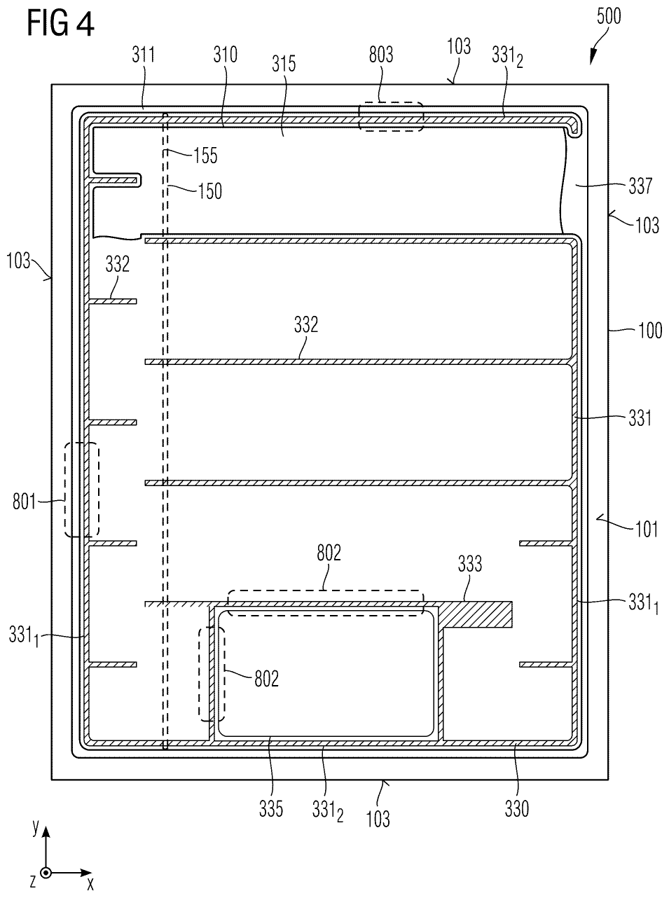

FIG. 4 shows a plan view of the front side of a silicon carbide body 100, wherein one illustrated stripe-shaped gate structure 150 is representative for a plurality of trench gate structures extending parallel to the y-axis. A first main surface 101 at the front side of the silicon carbide body 100 and a lateral surface 103 of the silicon carbide body 100 may form a front side chip edge with four straight portions oriented orthogonal to each other.

A gate metallization 330 may include a gate pad 335, an integrated gate resistor 333, gate conductors 331, 332, gate contact structures and clamp contact structures.

The gate pad 335 may be formed close to the chip edge, e.g., along a central part of a straight portion of the chip edge. The gate pad 335 may include a thin layer portion and a thick metallization formed on the thin layer portion. The thin layer portion may include elemental titanium, a titanium compound, e.g. titanium nitride (TiN), elemental tantalum (Ta), and/or a tantalum compound, e.g. tantalum nitride (TaN). The thick metallization may include elemental copper (Cu), a copper alloy, elemental aluminum (Al), an aluminum alloy and/or a copper aluminum alloy.

The integrated gate resistor 333 may include doped polycrystalline silicon. A first side of the integrated gate resistor 333 may be electrically connected to the gate pad 335. A second, opposite side of the integrated gate resistor 333 may be directly connected with at least one of the gate conductors 331, 332. The gate conductors 331, 332 include or consist of a thin layer portion. The thin layer portion of the gate conductors 331, 332 and the thin layer portion of the gate pad 335 may have the same structural configuration. For example, both thin layer portions may include the same material and may have the same thickness or may be formed from the same layer stack.

The gate conductors 331, 332 may include stripe-shaped first gate runners 331₁, stripe-shaped second gate runners 331₂, and stripe-shaped gate fingers 332. The first gate runners 331₁ have a longitudinal extension parallel to the y-axis. The second gate runners 331₂ have a longitudinal extension parallel to the x-axis. The first and second gate runners 331₁, 331₂ form a frame along the chip edge, wherein the frame may have a gap 337. Longitudinal axes of the gate fingers 332 are parallel to the x-axis and intersect the gate structures 150. Each gate finger 332 is in contact with at least one gate runner 331. Each gate finger 332 electrically connects the gate electrodes 155 of a plurality of gate structures 150 directly or through gate contact structures. Each gate electrode 155 may be directly connected to a plurality of gate fingers 332.

A first load metallization 310 may include a load pad 315 an edge conductor 311, load contact structures and edge contact structures. The load pad 315 may include a thin layer portion and a power metallization formed on the thin layer portion. The thin layer portion may include elemental titanium, a titanium compound, e.g. titanium nitride (TiN), elemental tantalum (Ta), and/or a tantalum compound, e.g. tantalum nitride (TaN). The power metallization may include elemental copper (Cu), a copper alloy, elemental aluminum (Al), an aluminum alloy or a copper aluminum alloy. The power metallization of the load pad 315 and the thick metallization of the gate pad 335 may have the same structural configuration.

The load pad 315 may cover the gate fingers 332. Alternatively, the load pad 315 may include a plurality of interconnected load pad sections, wherein the gate fingers 332 are formed in gaps between neighboring load pad sections.

The edge conductor 311 may form a frame around the load pad 315, wherein the sections of the frame are formed between the gate runners 331₁, 331₂ and the chip edge. The edge conductor 311 includes a thin layer portion and may include a power metallization formed on the thin layer portion. The thin layer portion of the edge conductor 311 and the thin layer portion of the load pad 315 may have the same structural configuration and may form a contiguous structure extending through the gap 337 in the gate runner frame.

The silicon carbide device 500 may include at least one of a first clamp part 801 formed along a first gate runner 331₁, a second clamp part 802 formed along an edge of the gate pad 335, and a third clamp part 803 formed along a second gate runner 331₂.

The first clamp part 801 may extend along one or both first gate runners 331₁. Along each first gate runner 331₁ one single portion of the first clamp part 801 may be formed. The single portion may extend across at least half of the length of the first gate runner 331₁ or across at least 90%. More than one portion may be formed along each first gate runner 331₁.

The second clamp part 802 may extend along one, two, three or all edges of the gate pad 335. The second clamp part 802 may be one contiguous structure or may include two or more laterally separated portions.

The third clamp part 803 may extend along one or both second gate runners 331₂. Along each second gate runner 331₂ one single portion of the third clamp part 803 may be formed. The single portion may extend across at least half of the length of the second gate runner 331₂ or across at least 90%. More than one portion may be formed along each second gate runner 331₂.

A silicon carbide device 500 may exclusively include a first clamp part 801, a second clamp part 802, or a third clamp part 803, may include any combination of two of said clamp parts 801, 802, 803 or may include all three clamp parts 801, 802, 803.

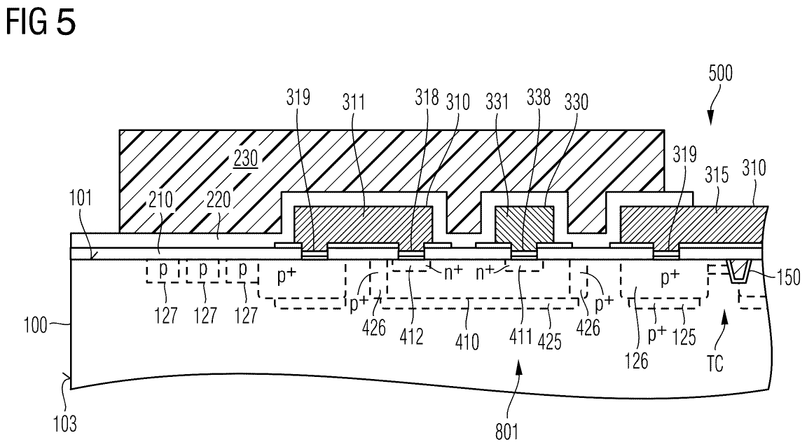

FIG. 5 shows a first clamp part 801 with a first clamp region 411 and a second clamp region 412 extending into a well region 410 as illustrated in FIGS. 3 and 4. The first clamp region 411 is formed directly below a first gate runner 331₁ with a longitudinal axis parallel to the y-axis. The second clamp region 412 is formed directly below a portion of an edge conductor 311 between the first gate runner 331₁ and the lateral surface 103 of the silicon carbide body 100. A first load contact structure 319 forms a low-resistive ohmic contact between a load pad 315 and a p conductive doped region at a side of the first gate runner 331₁ opposite to the edge conductor 311. A second load contact structure 319 forms a low-resistive ohmic contact between the edge conductor 311 and a further p conductive doped region.

The p conductive doped regions may be connection regions 126 extending from the first main surface 101 to the shielding regions 125 as described above or may result from the same implantation process(es) as used for forming the connection regions 126.

Laterally separated guard rings 127 extend between the well region 410 and the lateral surface 103 from the first main surface 101 into the silicon carbide body 100. A dielectric passivation layer 220 extending inwardly from the lateral surface 103 to beyond an outer edge of the load pad 315 covers the edge conductor 311 and the first gate runner 331₁. An imide layer 230 may cover a portion of the passivation layer 220.

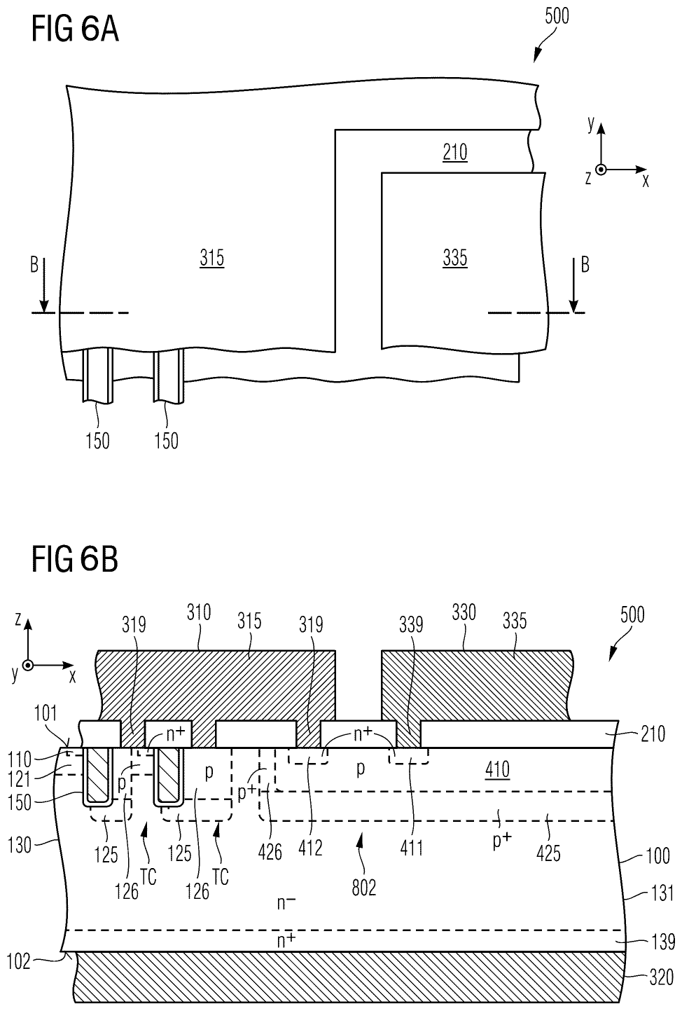

FIGS. 6A and 6B show a second clamp part 802 with the first clamp region 411 formed directly below an outer portion of a gate pad 335 and with the second clamp region 412 formed directly below a portion of a load pad 315 oriented to the gate pad 335. The well region 410 spans a gap between the load pad 315 and the gate pad 335.

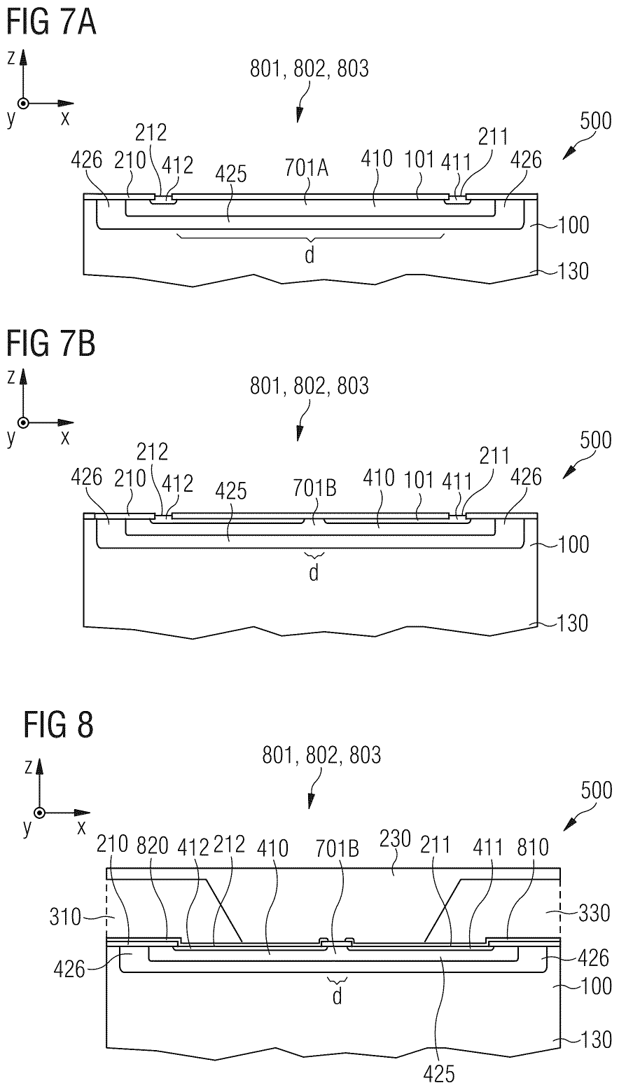

FIG. 7A shows a side view of an exemplary silicon carbide device 500 in accordance with the disclosure provided above with regard to any of the above referenced Figures, in which like reference numerals refer to similar or identical elements. The features of the various illustrated examples can be combined unless they exclude each other. As described above a bidirectional clamp (such as bidirectional clamp 800) may be formed at least in the first clamp part 801, the second clamp part 802, and/or the third clamp part 803 of the silicon carbide device 500. FIG. 7A illustrates certain elements of the first clamp part 801 (as shown in FIGS. 1 to 5), of the second clamp part 802 (as shown in FIGS. 1 to 4, 6A and 6B), and of the third clamp part (shown in FIGS. 1 to 4) while omitting other elements for illustrative purpose (such as the transistor cell TC). These omitted elements may still be present in the context of FIG. 7A (but are not shown).

In particular, the first clamp region 411 and the second clamp region 412 may form a bidirectional clamp (as described further above). The first clamp region 411 may be electrically connected with a gate electrode 155 of the transistor cell TC (not shown in FIG. 7A). For example, the first clamp region 411 may be electrically connected with the gate electrode 155 via a gate metallization 330 (as described further above in more detail). The second clamp region 412 may be electrically connected with a source region 110 of the transistor cell TC (not shown in FIG. 7A). For example, the second clamp region 412 may be electrically connected with a load metallization 310 (as also described further above in more detail).

A well region 410 may be arranged between the first clamp region 411 and the second clamp region 412 and may laterally surround each of the first clamp region 411 and the second clamp region 412.

Laterally surrounding may mean that the well region surrounds the first clamp region and the second clamp region in a lateral direction (that is substantially parallel to a main surface of the semiconductor body) on all sides within the silicon carbide body. For example, the well region may form a contiguous shell enclosing the first clamp region and the second clamp region in the silicon carbide body in the lateral direction.

The well region 410 may comprise an intermediate region 701A that is located between the first clamp region 411 and the second clamp region 412. The intermediate region 701A may have a width that equals a distance d between the first clamp region 411 and the second clamp region 412.

The well region 410, the first clamp region 411, and the second clamp region 412 may extend from a first main surface 101 of the silicon carbide device 500 into the silicon carbide device 500.

The silicon carbide device 500 may further comprise buried region 425 and one or more lateral region 426 (as further described above in more detail), which together may laterally surround the well region 410 (such as form a contiguous shell enclosing the well region 410 in the silicon carbide body 100). In examples, a mean net dopant density N₂ of the buried region 425 and the one or more lateral regions 426 is higher than a mean net dopant density N₁ of the well region 410. Likewise, a mean net dopant density N₃ of the one or more lateral region 426 may be higher than the mean net dopant density N₁ of the well region 410.

The silicon carbide device 500 may further comprise a transistor cell TC (not shown in FIG. 7A) that includes gate electrode 155 (being electrically connected to the first clamp region 411 via gate metallization 330), source region 110 (being electrically connected to the second clamp region 412 via load metallization 310), body region 121, and drift/drain region 130.

An interlayer dielectric 210 may be formed on the first main surface 101. The interlayer dielectric may isolate the silicon carbide body 100 from the gate metallization 330 and/or from the load metallization 310 (not shown in FIG. 7A). The interlayer dielectric 210 may comprise first and second openings 211, 212 that may allow forming an electrical contact between the first clamp region 411 and the gate metallization 330 and between the second clamp region 412 and the load metallization 310.

As also discussed above, the first clamp region 411 and the second clamp region 412 may have a (same) first conductivity type (e.g., p-doped or n-doped). The well region 410 is of a second conductivity type (being different from the first conductivity type of the first clamp region 411 and the second clamp region 412). As such, the first clamp region 411 and the well region 410 may form a first pn-junction, and the second clamp region 412 and the well region 410 may form a second pn-junction.

In some embodiments, the first clamp region 411 and the second clamp region 412 may have the same conductivity type as the source region 110. In other embodiments, the first clamp region 411 and the second clamp region 412 may have a different conductivity type as compared to the source region 110.

In case the first clamp region 411 and the second clamp region 412 have the same conductivity type as the source region 110 (i.e., the first conductivity type), the drain/drift region 130 of the silicon carbide body 100 may also have the first conductivity type. Then, the body region (not shown in FIG. 7A) of the transistor cell (not shown in FIG. 7A) may have the second conductivity type, and the buried region 425 and the one or more lateral regions 426 may also have the second conductivity type (being the same conductivity type that the well region 410 has). In this case, the buried region 425 and the drain/drift region form a pn junction, and the buried region 425 and the well region 410 form a unipolar junction.

In case the first clamp region 411 and the second clamp region 412 have a first conductivity type and the source region 110 may have a second conductivity type (being different from the first conductivity type), the drain/drift region 130 of the silicon carbide body 100 may also have the second conductivity type. Then, the body region (not shown in FIG. 7A) of the transistor cell (not shown in FIG. 7A) may have the first conductivity type, and the buried region 425 and the one or more lateral regions 426 may also have the first conductivity type (being different from the second conductivity type that the well region 410 has). In this case, the buried region 425 and the drain/drift region form a pn junction, and the buried region 425 and the well region 410 also form a pn junction. In other words, in this case, the buried region 425 and the one or more lateral regions 426 may form a junction isolation that isolates the well region 410 from the drain/drift region 130.

In a typical silicon carbide device 500 a distance d between the first clamp region 411 and the second clamp region 412 (such as shown in the above referenced Figures and as indicated in FIG. 7A) may be around 25 μm. This distance d may be based on a distance between the gate metallization 330 that is in electrical contact with the first clamp region 411 and the load metallization 310 that is in electrical contact with the second clamp region 412, because the first clamp region 411 and the second clamp region 412 are typically arranged under the gate metallization 330 and the load metallization 310, respectively. For example, in case the gate metallization 330 and the load metallization 310 become too close, a short circuit might be present.

Typically, the semiconductor device 500 extends in a direction that is perpendicular to the plane that is shown in FIG. 7A (indicated as y-direction FIG. 7A). As such the elements shown in FIG. 7A may also extend in the y-direction. Typically, the first clamp region 411 and the second clamp region 412 may extend in parallel in the y-direction. In such a case, the distance d between the first clamp region 411 and the second clamp region 412 may be given along the x-axis (indicated in FIG. 7A) and this distance will be the same or substantially the same along the y-direction (in which the first clamp region 411 and the second clamp region 412 extend). In such a case, the distance along the x-axis may be the shortest distance between the first clamp region 411 and the second clamp region 412. However, other geometries of the first clamp region 411 and the second clamp region may also be possible (e.g., that they do not extend in parallel in the y-axis). In such cases, a shortest distance between the first clamp region 411 and the second clamp region 412 is the distance between the first clamp region 411 and the second clamp region 412 that is minimal among all distances between the first clamp region 411 and the second clamp region 412. The distance d indicated in FIG. 7A may indicate the shortest distance between the first clamp region 411 and the second clamp region 412.

As discussed above, an avalanche breakdown of the pn junction between the first clamp region 411 and the well region 410 may define the clamp voltage for positive voltage transients between gate electrode 155 and source region 110. The transient may be directly short-circuited through the forward-biased pn junction between the well region 410 and the second clamp region 412. Similarly, an avalanche breakdown of the pn junction between the second clamp region 412 and the well region 410 may define the clamp voltage for negative voltage transients between the gate electrode 155 and the source region 110.

For example, in case the first clamp region 411 and the second clamp region 412 have the negative doping type, the clamp voltage of the bidirectional clamp for positive voltages is determined mainly by the p-doping of the well region 410 in the intermediate region 701A located between the first clamp region 411 and the second clamp region 412. However, the clamp voltages are substantially independent from the distance d between the first clamp region 411 and the second clamp region 412.

In case a voltage between the gate electrode 155 and the source region 110 exceeds the positive clamp voltage or falls below the negative clamp voltage, a discharge event may occur and current may flow from gate electrode 155 to the source region via the first clamp region 411 and the second clamp region 412 or vice versa.

The resistance of the bidirectional clamp during such a discharge event may depend on the distance d between the first clamp region 411 and the second clamp region 412. As discussed above, in a discharge event, there may be an avalanche breakdown of one of the pn-junction formed by the first clamp region 411 and the well region 410 or the pn-junction formed by the second clamp region 412 and the well region 410. In this case, the current may flow through intermediate region 701A, which thereby contributes to the resistance of the bidirectional clamp. The resistance of the bidirectional clamp may determine the amount of charge that can flow through the bidirectional clamp per unit of time. This means that the smaller the resistance of the bidirectional clamp is, the more charge can be discharged in a given unit of time. In other words, the smaller the distance d between the first clamp region 411 and the second clamp region 412, the smaller the resistance of the bidirectional clamp and the larger the amount of charge that can be discharged in a given unit of time. This means that in case of a discharge event, decreasing the (shortest) distance d between the first clamp region 411 and the second clamp region 412 may not alter or not substantially alter the clamping voltages, but may increase the amount of charge that can be discharged via the bidirectional clamp.

In FIG. 7B, a side view of a silicon carbide device 500 according to the present disclosure is illustratively shown. Unless stated otherwise, the silicon carbide device 500 comprises and shows the same elements as the silicon carbide device 500 of FIG. 7A with a smaller (shortest) distance d between the first clamp region 411 and the second clamp region 412 as compared to FIG. 7A. For example, the (shortest) distance d between the first clamp region 411 and the second clamp region 412 may be equal to or less than 10 μm. In other examples, the (shortest) distance between the first clamp region 411 and the second clamp region 412 may be equal to or less than 7.5 μm or 5 μm or 4 μm or 3 μm or 2 μm or 1 μm. In some examples, the (shortest) distance between the first clamp region 411 and the second clamp region 412 may be not less than 0.5 μm, for example.

The first clamp region 411 and the second clamp region 412 may extend under the interlayer dielectric 210. The first clamp region 411 may extend in a first direction and the second clamp region 412 may extend in a second direction that is directed towards the first direction (the first second directions lying on a same straight line but pointing towards each other). As such, the shortest distance between the first clamp region 411 and the second clamp region 412 may be reduced. While FIG. 7B shows that both, the first clamp region 411 and the second clamp region 412 extend towards each other, it is also contemplated that only one of the first clamp region 411 and the second clamp region 412 are extended in a direction that points towards the other clamp region, respectively.

In other words, a width of the intermediate region 701B of the well region 410 that is located between the first clamp region 411 and the second clamp region 412 may be less than a width of at least one of the first clamp region 411 and the second clamp region 412 (e.g., 1.5-times less, two-times less, three-times less, five-times less, or more-times less). The width of the intermediate region 701B can be 1 μm, 2 μm, 3 μm, 4 μm or 5 μm (or also larger such as 10 μm) for example. The width of the intermediate region 710B may also be 0.5 μm, which may lead to a lower breakdown voltage. The width of the first clamp region 411 and the second clamp region 412 can be 20 μm, 10 μm, 5 μm or 1 μm. In one embodiment, the intermediate region 701B has a width of approximately 2 μm and the first clamp region 411 and the second clamp region 412 have a width of 10 μm. For example, the width of the intermediate region 701B, the width of the first clamp region 411, and the width of the second clamp region 412 may be given in the same direction (such as in the direction of the shortest distance indicated in FIG. 7B, which coincides with the direction of the x-axis in FIG. 7B). As discussed above, the width of the intermediate region 701B may be equal to or substantially equal to the (shortest) distance d between the first clamp region 411 and the second clamp region 412.

In FIG. 8, a side view of silicon carbide device 500 according to the present disclosure is illustratively shown. Unless stated otherwise, the silicon carbide device 500 comprises and shows the same elements as the silicon carbide device 500 of FIG. 7B with a smaller (shortest) distance d between the first clamp region 411 and the second clamp region 412 as compared to FIG. 7A. In addition, to the elements shown in FIG. 7B, the example shown in FIG. 8 comprises a first metal layer 810 and a second metal layer 820. In addition, the load metallization 310 and the gate metallization 330, which are not shown in FIGS. 7A-7B, are illustrated. In addition, an isolation layer 230 is shown in FIG. 8.

The first metal layer 810 may be disposed over the first clamp region 411. For example, the first metal layer 810 may be disposed over the interlayer dielectric 210 above the one or more lateral regions 426 and above an outer region of the well region 410 adjacent to the first clamp region 411. The first metal layer 810 may extend into the first opening 211 of the interlayer dielectric 210 (e.g., by forming a step) and contact the first clamp region 411. In some examples, the first metal layer 810 may cover the entire first opening of the interlayer dielectric 210 over the first clamp region 411. The first metal layer 810 may extend over a middle part of the interlayer dielectric 210 (e.g., by forming a step) that is located over the intermediate region 701B of the well region 410.

The first metal layer may be electrically connected with the gate metallization 330. As discussed above, the gate metallization 330 may include a gate pad 335, gate conductors 331 formed on the interlayer dielectric 210, gate contact structures 339 extending from the gate pad 335 and/or from the gate conductor 331 through openings in the interlayer dielectric 210 to the gate electrodes 155. The gate metallization 330 may include clamp contact structures 338 extending from the gate pad 335 and/or from the gate conductor 331 through the first opening 211 in the interlayer dielectric 210 to the first clamp regions 411. As such, the first clamp region 411 may be electrically connected to the gate electrode 155 via the first metal layer 810 and via the gate metallization 330.

As shown in FIG. 8, the first and second openings 211 and 212 of the interlayer dielectric 210 may be enlarged as compared to the exemplary silicon carbide device shown in FIGS. 7A-7B. For example, a width of the first opening 211 over the first clamp region 411 may be substantially equal to the width of the first clamp region 411. In such a case, the clamp contact structure 338 may only partially cover the part of the first metal layer 810 that is disposed over the first clamp region 411 (such as covering only 70% or only 60% or only 50% or only 40% or only 30% of the part of the first metal layer 810 that is disposed over the first clamp region). The first metal layer 810 may comprise at least one of Ti, TiN, TaN, MoN or Ni. The first metal layer may have a thickness of 100 nm to 300 nm, in examples.

In addition, (optionally) a second metal layer 820 may be disposed over the second clamp region 412. For example, the second metal layer 820 may be disposed over the interlayer dielectric 210 above the one or more lateral regions 426 and above an outer region of the well region 410 adjacent to the second clamp region 412. The second metal layer 820 may extend into the second opening 212 of the interlayer dielectric 210 (e.g., by forming a step) and contact the second clamp region 412. In some examples, the second metal layer 820 may cover the entire second opening 212 of the interlayer dielectric 210 over the second clamp region 412. The second metal layer 820 may extend over a middle part of the interlayer dielectric 210 (e.g., by forming a step) that is located over the intermediate region 701B of the well region 410. The first metal layer 810 and the second metal layer 820 may be spaced apart from each other on the middle part of the interlayer dielectric 210.

The second metal layer 820 may be electrically connected with the load metallization 310. As discussed above, the load metallization 310 may include a load pad 315, edge conductors 311 formed on the interlayer dielectric 210, load contact structures 319 extending from the load pad 315 through openings in the interlayer dielectric 210 to the source regions 110, to the body regions 121, and, if applicable, to the second clamp region 412 (through the second opening 212), and edge contact structures 318 extending from the edge conductor 311 through the second opening 212 in the interlayer dielectric 210 to the second clamp region 412. As such, the second clamp region 412 may be electrically connected to the source region 110 via the second metal layer 820 and via the load metallization 310.

A width of the second opening 212 over the second clamp region 412 may be substantially equal to the width of the second clamp region 412. In such a case, the edge contact structure 318 (or the load contact structure 319) may only partially cover the part of the second metal layer 820 that is disposed over the second clamp region 412 (such as covering only 70% or only 60% or only 50% or only 40% or only 30% of the part of the first metal layer 810 that is disposed over the first clamp region). The second metal layer 820 may comprise at least one of Ti, TiN, MoN, TaN or Ni. The second metal layer may have a thickness of 100 nm to 300 nm, in examples. The first metal layer 810 and/or the second metal layer 820 may further decrease the resistance of the bidirectional clamp.

The isolation layer 230 (which may comprise an imide) may electrically isolate the load metallization 310 and the gate metallization 330. The isolation layer may be disposed over the portion of the first metal layer 810 that is not covered by the gate metallization 330 and over the portion of the second metal layer that is not covered by the load metallization 310. In addition, the isolation layer 230 may be disposed over the middle portion of the interlayer dielectric 210 which is not covered by the first metal layer 810 nor by the second metal layer 820. In addition, the isolation layer 230 may be disposed on top of the clamp contact structures 338 and on top of the edge contact structure 318/load contact structure 319.

In addition to or as an alternative to the above described disclosure, the shortest distance d between the first clamp region 411 and the second clamp region 412 can be located at the side of the first clamp region 411 and the second clamp region 412 (such as in the y-direction in the above referenced FIGS. 7A-8, as will be described in more detail below). This may also increase the current that can flow from the first clamp region 411 to the second clamp region 412 (or vice versa) in a given instant of time.

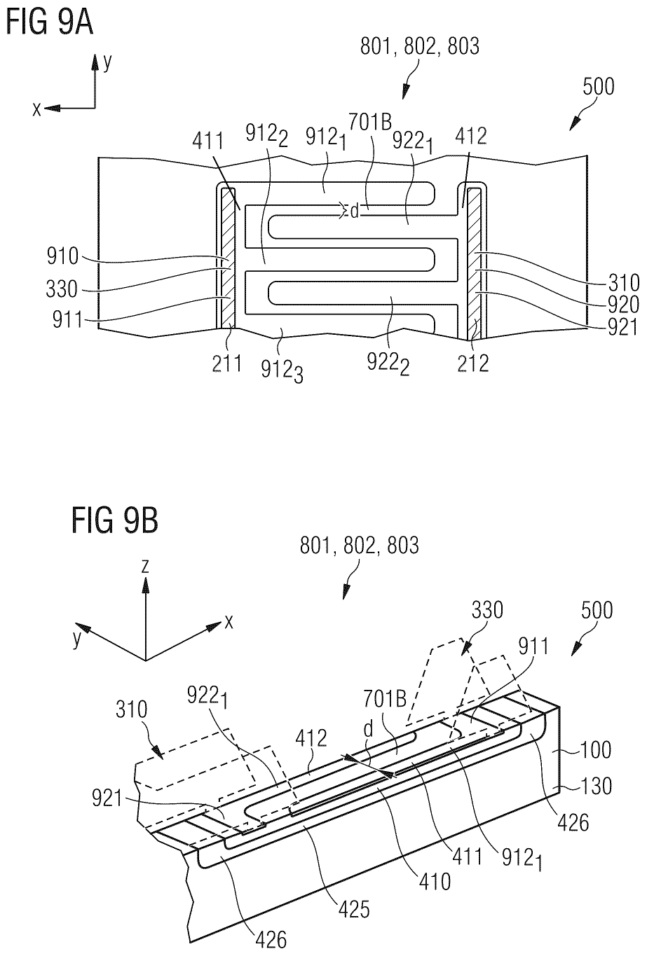

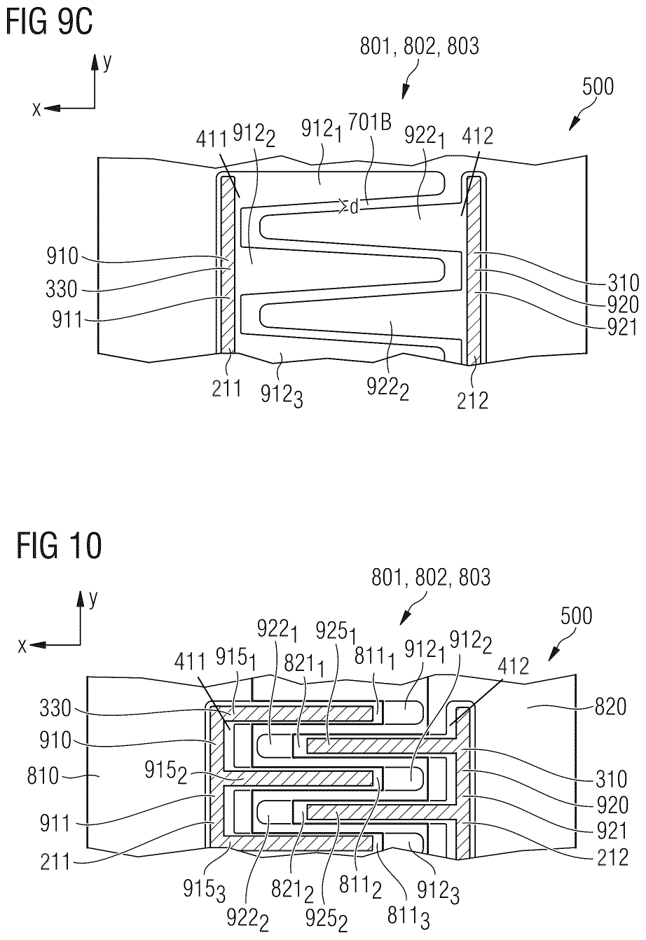

FIGS. 9A-9B show a top view and a 3D-view of an exemplary silicon carbide device 500, respectively, in accordance with the disclosure provided above with regard to any of the above referenced Figures, in which like reference numerals refer to similar or identical elements. The features of the various illustrated examples can be combined unless they exclude each other. As described above a bidirectional clamp (such as bidirectional clamp 800) may be formed at least in the first clamp part 801, the second clamp part 802, and/or the third clamp part 803 of the silicon carbide device 500. FIGS. 9A-9B illustrate certain elements of the first clamp part 801 (as shown in FIGS. 1 to 5), of the second clamp part 802 (as shown in FIGS. 1 to 4, 6A and 6B), and of the third clamp part (shown in FIGS. 1 to 4) while omitting other elements for illustrative purpose (such as the transistor cell TC). These omitted elements may still be present in the context of FIGS. 9A-9B (but are not shown).

The silicon carbide device 500 comprises the first clamp region 411 and the second clamp region 412. In this example, the first clamp region 411 forms a first comb 910, which includes one or more first teeth 912₁, 912₂, 912₃ and the second clamp region 412 forms a second comb 920 which includes one or more second teeth 922₁, 922₂. Each one of the one or more first teeth 912₁, 912₂; 912₃ and the one or more second teeth 922₁, 922₂ may have substantially a rectangular shape with a short side and a long side.

The one or more first teeth 912₁, 912₂; 912₃ may be connected to the gate metallization 330 at one of the short sides (e.g., through an opening in the interlayer dielectric 210, as described above). The one or more second teeth 922₁, 922₂ may be connected to the load metallization 310 at one of the short sides (e.g., through an opening in the interlayer dielectric 210, as described above) opposing the short side of the one or more first teeth 912₁, 912₂; 912₃ that is connected to the gate metallization 330. The one or more first teeth 912₁, 912₂; 912₃ and the one or more second teeth 922₁, 922₂ are arranged such that a long side of one of the one or more first teeth 912₁, 912₂; 912₃ is located next to a long side of one of the one or more second teeth 922₁, 922₂ (e.g., they are arranged in parallel or substantially in parallel to each other) with a distance d between them. This distance d may be the shortest distance between the first clamp region 411 and the second clamp region 412. As discussed above, with regard to FIGS. 7B-8, the intermediate region 701B may be located between two adjacent teeth of the first comb 910 (formed by the first clamp region 411) and the second comb 920 (formed by the second clamp region 412).

Optionally the first comb 910 may comprise a first shaft 911 that connects the one or more first teeth 912₁, 912₂; 912₃ and the second comb 920 may comprise a second shaft 921 that connects the one or more second teeth 922₁, 922₂. For example, the first shaft 911 may be arranged orthogonal to the one or more first teeth 912₁, 912₂; 912₃ at one end of the one or first teeth 912₁, 912₂; 912₃. Likewise, the second shaft 921 may be arranged orthogonal to the one or more second teeth 922₁, 922₂ at one end of the one or second teeth 922₁, 922₂. In this case, the gate metallization 330 may be connected to the first shaft 911 (through one or more openings in the interlayer dielectric 210), and the load metallization 310 may be connected to the second shaft 921 (through one or more openings in the interlayer dielectric 210).

The first shaft 911 and the second shaft 921 may have a length of 100 μm, 200 μm, 500 μm, 1000 μm, 2000 μm or 3000 μm. The short side of the first teeth 912₁, 912₂; 912₃ and the second teeth 922₁, 922₂ may have a length of 0.5 μm and the long side of the first teeth 912₁, 912₂; 912₃ and the second teeth 922₁, 922₂ may be 1 μm, 2 μm or 5 μm. Of course, other lengths may be possible and contemplated by the present disclosure and the mentioned lengths are only intended to serve as examples.

While FIG. 9A shows three first teeth 912₁, 912₂; 912₃ connected with a first shaft 911 and two second teeth 922₁, 922₂, connected with a second shaft 921, the number of first and second teeth can be more or less. For example, the first comb 910 could also include only one first tooth 912₁ and the second comb 920 could include only one second tooth 922₁.

The first comb 910 and second comb 920 may have their respective teeth intertwined with the (shortest) distance d being located between two respective adjacent teeth of the first comb 910 and the second comb 920. A distance between the first teeth 912₁, 912₂; 912₃ and the second shaft 921 is equal to or greater than the distance d between the first teeth 912₁, 912₂; 912₃ and the second teeth 922₁, 922₂, which may be the shortest distance between the first clamp region 411 and the second clamp region 412.

The first teeth 912₁, 912₂; 912₃ and the second teeth 922₁, 922₂ may alternate, i.e., one of the first teeth is disposed adjacent to one of the second teeth, which is disposed adjacent to another one of the first teeth, which again is disposed adjacent to another one of the second teeth, and so on. The distance between two subsequent teeth (one being one of the first teeth and one being one of the second teeth) may be substantially equal and may be substantially the shortest distance d between the first clamp region and the second clamp region.

FIG. 9C shows a top view of an exemplary silicon carbide device 500. The silicon carbide device of FIG. 9C is the same as the one shown in FIGS. 9A and 9B except that the shape of the first teeth 912₁, 912₂; 912₃ and the second teeth 922₁, 922₂ is trapezoidal. The first teeth 912₁, 912₂; 912₃ may have a larger width where the first teeth 912₁, 912₂; 912₃ adjoin the first shaft 911 and a smaller width where the first teeth 912₁, 912₂; 912₃ are proximate to the second shaft 921. Likewise, the second teeth 922₁, 922₂ may have a larger width where the second teeth 922₁, 922₂ adjoin the second shaft 921 and a smaller width where the second teeth 922₁, 922₂ are proximate to the first shaft 911. This may lead to a more uniform current distribution as compared to a silicon carbide device with rectangular teeth.

FIG. 10 shows a silicon carbide device 500 in accordance with the disclosure provided with respect to FIGS. 9A-9B, additionally with a first metal layer 810 and second metal layer 820 (similarly as described above with regard to FIG. 8).

A first metal layer 810 may be disposed over the first shaft 911 and over at least a portion of each of the plurality of first teeth 912₁, 912₂; 912₃ of the first clamp region 411. As discussed above, the first metal layer 810 may comprise at least one of Ti, TiN, MoN, TaN and Ni. The first clamp region 411 may be connected to the gate metallization 330 via the first metal layer 810. The first metal layer 810 may have a thickness of 100 nm to 300 nm, in examples. The first metal layer 810 may include a plurality of first teeth 811₁, 811₂, 811₃ (e.g., one tooth for each tooth of the plurality of first teeth 912₁, 912₂; 912₃ of the first comb 910 formed by the first clamp region 411) that partially cover the plurality of first teeth 912₁, 912₂; 912₃ of the first comb 910. As discussed above with regard to FIG. 8, the first metal layer 810 may be placed in an opening of the interlayer dielectric 210 that is disposed on the first main surface 101 of the silicon carbide body 110. Accordingly, the opening of the interlayer dielectric may have a comb-shape when viewed from above that substantially allows the first metal layer to contact the first shaft 911 and at least parts of the plurality of first teeth 912₁, 912₂; 912₃ of the first comb 910 of the first clamp region 411. For example, the each one of the plurality of first teeth 811₁, 811₂, 811₃ of the first metal layer 810 may cover 20% or 30% or 40% or 50% or 60% or 70% or 80% or 90% of a respective one of the plurality of first teeth 912₁, 912₂; 912₃ of the first clamp region 411.

In addition, the gate metallization 330 may comprise a plurality of first fingers 915₁, 915₂, 915₃ where each of the first fingers 915₁, 915₂, 915₃ forms a contact with a respective one of the first teeth 811₁, 811₂, 811₃ of the first metal layer 810. For example, each of the first finger 915₁, 915₂, 915₃ of the gate metallization 330 may cover a respective one of the first teeth 811₁, 811₂, 811₃ of the first metal layer 810. As such, the first clamp region 411 may be connected to the gate electrode 155 via the first metal layer 810, via the first fingers 915₁, 915₂, 915₃ of the gate metallization and via the remainder of the gate metallization 330 (not shown in FIG. 10).

Likewise, a second metal layer 820 may be disposed over the second shaft 921 and over at least a portion of each of the plurality of second teeth 922₁, 922₂ of the second clamp region 412. As discussed above, the second metal layer 820 may comprise at least one of Ti, TiN, MoN, TaN, W, and Ni. The second clamp region 412 may be connected to the load metallization 310 via the second metal layer 820. The second metal layer 820 may have a thickness of 100 nm to 300 nm, in examples. The second metal layer 820 may include a plurality of second teeth 821₁, 821₂ (e.g., one tooth for each tooth of the plurality of second teeth 922₁, 922₂ of the second comb 920 formed by the second clamp region 412) that partially cover the plurality of second teeth 922₁, 922₂ of the second comb 920. As discussed above with regard to FIG. 8, the second metal layer 820 may be placed in an opening of the interlayer dielectric 210 that is disposed on the first main surface 101 of the silicon carbide body 110. Accordingly, the opening of the interlayer dielectric may have a comb-shape when viewed from above that substantially allows the second metal layer to contact the second shaft 921 and at least parts of the plurality of second teeth 922₁, 922₂; 922₃ of the second comb 920 of the second clamp region 412. For example, the each one of the plurality of second teeth 821₁, 821₂ of the second metal layer 820 may cover 20% or 30% or 40% or 50% or 60% or 70% or 80% or 90% of a respective one of the plurality of second teeth 922₁, 922₂ of the second clamp region 412. The plurality of first teeth 811₁, 811₂, 811₃ of the first metal layer 810 and the plurality of second teeth 821₁, 821₂ of the second metal layer 820 may be intertwined (just as the teeth of the first and second combs 910, 920) and may not be in touch with each other (such as spaced apart from each other).

In addition, the load metallization 310 may comprise a plurality of second fingers 925₁, 925₂ where each of the second fingers 925₁, 925₂ forms a contact with a respective one of the second teeth 821₁, 821₂. of the second metal layer 820. For example, each of the second fingers 925₁, 925₂ of the load metallization 310 may cover a respective one of the second teeth 821₁, 821₂ of the second metal layer 820. As such, the second clamp region 412 may be connected to the source region 110 via the second metal layer 820, via the second fingers 925₁, 925₂ of the load metallization and via the remainder of the load metallization 330 (not shown in FIG. 10).

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

Although the present disclosure is not so limited, the following numbered examples demonstrate one or more aspects of the disclosure.

Example 1: A silicon carbide device, comprising a transistor cell comprising a gate electrode and a source region; a first clamp region of a first conductivity type electrically connected with the gate electrode; a second clamp region of the first conductivity type electrically connected with the source region; and a well region of a second conductivity type laterally surrounding each of the first clamp region and the second clamp region, wherein a shortest distance between the first clamp region and the second clamp region is equal to or less than 10 μm.

Example 2: The silicon carbide device of example 1, wherein the well region comprises an intermediate region located between the first clamp region and the second clamp region, wherein a width of the intermediate region is less than a width of at least one of: the first clamp region or a width of the second clamp region, wherein the width of the intermediate region, the width of the first clamp region and the width of the second clamp region are given along a direction that points along the shortest distance between the first clamp region and the second clamp region.

Example 3: The silicon carbide device of examples 1 or 2, wherein the shortest distance between the first clamp region and the second clamp region is equal to or less than 5 μm.

Example 4: The silicon carbide device of any of the preceding examples, wherein the first clamp region and the second clamp region form a bidirectional clamp, wherein the bidirectional clamp is configured to carry a breakdown current of at least 2 A.

Example 5: The silicon carbide device of any of the preceding examples, wherein the well region, the first clamp region, and the second clamp region extend from a first main surface of the silicon carbide device into the silicon carbide device.

Example 6: The silicon carbide device of any of the preceding examples, further comprising at least one of: a gate metallization, wherein the gate metallization and the gate electrode are electrically connected and wherein the gate metallization and the first clamp region form a low-resistivity ohmic contact; or a load metallization, wherein the load metallization and the source region form a low-resistivity ohmic contact, and wherein the load metallization and the second clamp region form a low-resistivity ohmic contact.

Example 7: The silicon carbide device of any of examples 1 to 5, further comprising: a first metal layer disposed over the first clamp region; and a gate metallization, wherein the gate metallization and the gate electrode are electrically connected and wherein the gate metallization and the first metal layer are electrically connected.

Example 8: The silicon carbide device of example 7, wherein the first metal layer comprises at least one of Ti, TiN, MoN, TaN or Ni.

Example 9: The silicon carbide device of any of examples 1 to 5, 7 or 8, further comprising: a second metal layer disposed over the second clamp region; and a load metallization, wherein the load metallization and the source region (110) form a low-resistivity ohmic contact and wherein the load metallization and the second metal layer are electrically connected.

Example 10: The silicon carbide device of example 9, wherein the second metal layer comprises at least one of Ti, TiN, MoN, TaN or Ni.

Example 11: The silicon carbide device of any of examples 1 to 5, wherein the first clamp region forms a shape of a first comb, and the second clamp region forms a shape of a second comb (920).

Example 12: The silicon carbide device of example 11, wherein the first comb comprises a first shaft and a plurality of first teeth, wherein the second comb comprises a second shaft and a plurality of second teeth, wherein the plurality of first teeth is facing towards the second shaft, wherein the plurality of second teeth is facing towards the first shaft, wherein the plurality of first teeth and the plurality of second teeth extend substantially parallel to each other.

Example 13: The silicon carbide device of examples 11 or 12, wherein a distance between a first tooth of the plurality of first teeth and the second shaft is equal to or greater than a distance between the first tooth and a second tooth of the plurality of second teeth.

Example 14: The silicon carbide device of example 13, wherein the distance between the first tooth of the plurality of first teeth and the second tooth of the plurality of second teeth is the shortest distance between the first clamp region and the second clamp region.

Example 15: The silicon carbide device of any of examples 11 to 14, further comprising: a first metal layer disposed over the first shaft and over at least a portion of each of the plurality of first teeth; a gate metallization, wherein the gate metallization and the gate electrode are electrically connected and wherein the gate metallization and the first metal layer are electrically connected.

Example 16: The silicon carbide device of example 15, wherein the first metal layer comprises at least one of Ti, TiN, MoN, TaN or Ni.

Example 17: The silicon carbide device of example 16 further comprising: a second metal layer disposed over the second shaft and over at least a portion of each of the plurality of second teeth; and a load metallization, wherein the load metallization and the source region form a low-resistivity ohmic contact, and wherein the load metallization and the second metal layer are electrically connected.

Example 18: The silicon carbide device of example 17, wherein the second metal layer each comprises at least one of Ti, TiN, MoN, TaN or Ni.

Example 19: The silicon carbide device of example 18, wherein the gate metallization comprises a plurality of first fingers that partially cover the first metal layer; and wherein the load metallization comprises a plurality of second fingers that partially cover the second metal layer.

Example 20: The silicon carbide device of any of the preceding examples, wherein the source region is of the first conductivity type.

Example 21: The silicon carbide device of any of examples 1 to 20, further comprising a drain/drift region of the first conductivity type; a body region of the second conductivity type formed in the silicon carbide body; and a buried region of the second conductivity type, wherein the buried region and the drain/drift region form a pn junction, wherein the buried region and the well region form a unipolar junction.

Example 22: The silicon carbide device of example 21, wherein a mean net dopant density N₂ of the buried region is higher than a mean net dopant density N₁ of the well region.

Example 23: The silicon carbide device according to example 21 or 22, further comprising: a lateral region of the second conductivity type, wherein the lateral region laterally surrounds the well region, wherein the lateral region and the well region form a unipolar junction, and wherein a mean net dopant density N₃ of the lateral region is higher than the mean net dopant density N₁.

Example 24: The silicon carbide device of examples 1 to 19, wherein the source region is of the second conductivity type.

Example 25: The silicon carbide device of example 24, further comprising a drain/drift region of the second conductivity type; a body region of the first conductivity type formed in the silicon carbide body; and a buried region of the first conductivity type, wherein the well region and the buried region form a pn-junction.

What is claimed is:

1. A silicon carbide device, comprising:
a transistor cell comprising a gate electrode and a source region;
a first clamp region of a first conductivity type electrically connected with the gate electrode;
a second clamp region of the first conductivity type electrically connected with the source region; and
a well region of a second conductivity type laterally surrounding each of the first clamp region and the second clamp region,
wherein a shortest distance between the first clamp region and the second clamp region is equal to or less than 10 μm.

2. The silicon carbide device of claim 1,
wherein the well region comprises an intermediate region between the first clamp region and the second clamp region,
wherein a width of the intermediate region is less than at least one of a width of the first clamp region or a width of the second clamp region,
wherein the width of the intermediate region, the width of the first clamp region, and the width of the second clamp region are given along a direction that points along the shortest distance between the first clamp region and the second clamp region.

3. The silicon carbide device of claim 1,
wherein the shortest distance between the first clamp region and the second clamp region is equal to or less than 5 μm.

4. The silicon carbide device of claim 1,
wherein the first clamp region and the second clamp region form a bidirectional clamp,
wherein the bidirectional clamp is configured to carry a breakdown current of at least 0.33 A.

5. The silicon carbide device of claim 1,
wherein the well region, the first clamp region, and the second clamp region extend from a first main surface of the silicon carbide device into the silicon carbide device.

6. The silicon carbide device of claim 1, further comprising:
a gate metallization, wherein the gate metallization and the gate electrode are electrically connected, and wherein the gate metallization and the first clamp region form a low-resistivity ohmic contact.

7. The silicon carbide device of claim 1, further comprising:
a load metallization, wherein the load metallization and the source region form a low-resistivity ohmic contact, and wherein the load metallization and the second clamp region form a low-resistivity ohmic contact.

8. The silicon carbide device of claim 1, further comprising:
a metal layer disposed over the first clamp region; and
a gate metallization, wherein the gate metallization and the gate electrode are electrically connected, and wherein the gate metallization and the metal layer are electrically connected.

9. The silicon carbide device of claim 1, further comprising:
a metal layer disposed over the first clamp region,
wherein the metal layer comprises at least one of Ti, TiN, MoN, TaN and Ni.

10. The silicon carbide device of claim 1, further comprising:
a metal layer disposed over the second clamp region; and
a load metallization, wherein the load metallization and the source region form a low-resistivity ohmic contact, and wherein the load metallization and the metal layer are electrically connected.

11. The silicon carbide device of claim 1, further comprising:
a metal layer disposed over the second clamp region,
wherein the metal layer comprises at least one of Ti, TiN, MoN, TaN and Ni.

12. The silicon carbide device of claim 1,
wherein the first clamp region forms a first comb, and
wherein the second clamp region forms a second comb.

13. The silicon carbide device of claim 12,
wherein the first comb comprises a first shaft and a plurality of first teeth,
wherein the second comb comprises a second shaft and a plurality of second teeth,
wherein the plurality of first teeth and the plurality of second teeth each extend substantially parallel to each other,
wherein the plurality of first teeth and the plurality of second teeth are arranged in an alternating order,
wherein the first shaft connects the plurality of first teeth, and
wherein the second shaft connects the plurality of second teeth.

14. The silicon carbide device of claim 13,
wherein a distance between a first tooth of the plurality of first teeth and the second shaft is equal to or greater than a distance between the first tooth and a second tooth of the plurality of second teeth.

15. The silicon carbide device of claim 13,
wherein a distance between a first tooth of the plurality of first teeth and a second tooth of the plurality of second teeth is the shortest distance between the first clamp region and the second clamp region.

16. The silicon carbide device of claim 13, further comprising:
a first metal layer disposed over the first shaft and over at least a portion of each of the plurality of first teeth; and
a gate metallization, wherein the gate metallization and the gate electrode are electrically connected, and wherein the gate metallization and the first metal layer are electrically connected, and/or wherein the first metal layer comprises at least one of Ti, TiN, MoN, TaN and Ni.

17. The silicon carbide device of claim 16, further comprising:
a second metal layer disposed over the second shaft and over at least a portion of each of the plurality of second teeth; and
a load metallization, wherein the load metallization and the source region form a low-resistivity ohmic contact, and wherein the load metallization and the second metal layer are electrically connected, and/or wherein the second metal layer comprises at least one of Ti, TiN, MoN, TaN and Ni.

18. The silicon carbide device of claim 17,
wherein the gate metallization comprises a plurality of first fingers that partially cover the first metal layer, and
wherein the load metallization comprises a plurality of second fingers that partially cover the second metal layer.
